(19) United States
(12) Patent Application Publication
(10) Pub. No.: US 2026/0004032 A1
(43) Pub. Date: Jan. 1, 2026

(54) Method and system for continuous routing forecasting and operation of reservoir group under influence of river fragmentation

(71) Applicant: BUREAU OF HYDROLOGY, CHANGJIANG WATER RESOURCES COMMISSION, Wuhan (CN)

(72) Inventors: Haiyun CHENG, Wuhan (CN); Baofei FENG, Wuhan (CN); Wenjing NIU, Wuhan (CN); Jun ZHANG, Wuhan (CN); Yubin CHEN, Wuhan (CN); Yurong LI, Wuhan (CN); Yinshan XU, Wuhan (CN); Le WANG, Wuhan (CN); Yuni XU, Wuhan (CN)

(73) Assignee: BUREAU OF HYDROLOGY, CHANGJIANG WATER RESOURCES COMMISSION, Wuha (CN)

(21) Appl. No.: 19/304,627

(22) Filed: Aug. 20, 2025

Related U.S. Application Data
(63) Continuation of application No. PCT/CN2025/097432, filed on May 27, 2025.

(30) Foreign Application Priority Data
Jul. 1, 2024 (CN) 202410864878.3

(51) Int. Cl. G06F 30/28

(52) U.S. Cl. CPC G06F 30/28

(57) ABSTRACT

A method for continuous routing forecasting and operation of a reservoir group under influence of river fragmentation includes: decomposing and quantitatively characterizing a physical structure of a cascade reservoir group system based on an upstream-downstream hydraulic connection and a river channel composition feature, thereby decomposing a fragmented long river system into a river-reservoir system including water channel-reservoir-water channel basic units; generalizing an upstream-downstream relationship of each constituent unit in the system, quantifying a wave characteristic, and establishing upstream and downstream flood routing process equations; and extracting and quantifying an operation rule based on a historical reservoir operation scheme of the constituent unit, enabling a dynamic coupled feedback computation between an operation process and flood routing under different operation modes, and connecting the constituent units sequentially to complete continuous routing of the fragmented long river system.

### CROSS REFERENCE TO THE RELATED APPLICATIONS

This application is the continuation application of International Application No. PCT/CN2025/097432, filed on May 27, 2025, which is based upon and claims priority to Chinese Patent Application No. 202410864878.3, filed on Jul. 1, 2024, the entire contents of which are incorporated herein by reference.

### TECHNICAL FIELD

The present disclosure relates to the technical field of hydrology and water resources forecasting and operation, and in particular to a method and system for continuous routing forecasting and operation of a reservoir group under influence of river fragmentation.

### BACKGROUND

Accurate inflow flood forecasting serves as an important foundation for enabling refined and precise reservoir group operation and enabling scientific and rapid decision-making. However, reservoir operation alters the natural connectivity attributes of floods, forming a complex river-reservoir system composed of multiple river channel-reservoir-river channel basic units connected in series and parallel. The original natural river system will gradually evolve into a new fragmented pattern, disrupting the continuity of flood routing. Therefore, cascade reservoir group forecasting and operation faces significant challenges in the continuous routing of inflow flood processes.

Previous single-reservoir operation mainly relied on operation rules and expertise to address the continuity issue of flood routing. However, this technical approach can hardly satisfy the requirements of joint reservoir operation and continuous routing for long river systems, thereby urgently necessitating new solutions to solve the fragmentation problem. Therefore, clearing the fragmented nodes in long river systems and enabling “one-card pass” for the continuous inflow flood routing of cascade reservoirs is a key challenge currently faced in the field of hydrological forecasting and reservoir operation.

“One-card pass” refers to the flood routing process of cascade reservoir groups that can be computed continuously one by one. When the flood propagates to a reservoir, the forecast computation is performed by invoking the reservoir's operation rules, and the flood continues routing downstream to the next reservoir. The similarity between the flood routing process and “one-card pass” is “passing upon swiping,” allowing continuous downstream routing, while the difference lies in the absence of a physical card, and the “card” for each reservoir is unique.

### SUMMARY

Aiming to address the shortcomings of the prior art described above, an objective of the present disclosure is to provide a method and system for continuous routing forecasting and operation of a cascade reservoir group under influence of river fragmentation. The present disclosure analyzes the structure of a cascade reservoir group system, quantifies a flood routing process under the influence of reservoir operation, and achieves continuous automatic routing for a fragmented long river system.

To achieve the above objective, the present disclosure adopts the following technical solutions:

The present disclosure provides a method for continuous routing forecasting and operation of a cascade reservoir group under influence of river fragmentation, including:
S1: decomposing a physical structure of a cascade reservoir group system, and quantitatively characterizing a composition characteristic of a river-reservoir system as follows:

$$R = \{ {r}_{1} , {r}_{2} , {r}_{3} , … , {r}_{i} , … , {r}_{N} \} ;$$

where, R denotes the river-reservoir system; rᵢ denotes an i-th basic constituent unit of the system, and is a multi-dimensional vector for characterizing a location of the basic constituent unit, a number of upstream and downstream units, and an operation rule, with a number of dimensions determined by a specific number of characterizing factors; rᵢ denotes a serial number of the basic constituent unit of the system, i=1,2, . . . , N; and N denotes a number of basic constituent units, specifically a number of river channel-reservoir-river channel basic units composing the system;
S2: generalizing, based on the composition characteristic of the river-reservoir system, an upstream-downstream hydraulic connection of each constituent unit; quantifying a wave characteristic; and establishing upstream and downstream flood routing process equations, respectively:

$${Inf}_{i}^{t} = {q}_{1}^{t} + {q}_{2}^{t} + … + {q}_{M}^{t} ;$$

$${q}_{m}^{t} = f ( {q}_{m , out}^{t} , Δ {q}_{m , E}^{t} ) = w {(}_{m \to i}^{t} ) ;$$

where,

$${Inf}_{i}^{t}$$

denotes a reservoir inflow for the i-th basic constituent unit of the denotes an inflow from an m-th upstream unit to the i-th system at a time t, m³/s;

$${q}_{m}^{t}$$

denotes an inflow from an m-th upstream unit to the i-th basic constituent unit of the system at the time t, m³/s, m=1, 2, . . . , M;

$${q}_{m , o u t}^{t}$$

denotes a reservoir outflow from the m-th upstream unit at the time t, m³/s;

$$Δ {q}_{m , E}^{t}$$

denotes a flow influence at a unit reservoir cross-section at the time t after the reservoir outflow from the m-th upstream unit routes through a river channel and combines with a lateral inflow, m³/s; and

$$w {(}_{m \to i}^{t} )$$

denotes a flood routing process equation incorporating a basic wave characteristic, with a calculation result representing an inflow propagating to a reservoir of the i-th basic constituent unit of the system at the time t after the reservoir outflow from the m-th upstream unit combines with the lateral inflow;
S3: quantifying a reservoir operation rule for each constituent unit;
S4: adjusting a reservoir operation mode according to an operation objective of the reservoir in each constituent unit; and enabling a dynamic coupled feedback computation between an operation process and flood routing; and
S5: sequentially completing routing for each constituent unit; and enabling a serial connection through the upstream-downstream hydraulic connection and the routing process equation, thereby completing an overall river system computation.

Furthermore, in the step S1, the composition characteristic of the river-reservoir system refers to a series/parallel relationship and a connection method of the river channel-reservoir-river channel basic constituent units; the series/parallel relationship includes three types: series, parallel, and hybrid; and the connection method includes a head-to-tail connection and a connection via a natural river channel between an upstream basic constituent unit and a downstream basic constituent unit.

Furthermore, in the step S2, the wave characteristic includes kinematic wave, diffusive wave, inertial wave, dynamic wave, and interrupted wave; based on an occurrence frequency and an influence proportion, an upstream wave characteristic includes three types: kinematic wave, dynamic wave, and hybrid wave; and a downstream wave characteristic includes three types: kinematic wave, dynamic wave, and interrupted wave.

Furthermore, in the step S3, the quantifying a reservoir operation rule includes:
S31: organizing and analyzing a requirement of an existing reservoir operation regulation and operation plan, combining basic reservoir information and a characteristic parameter, and determining a reservoir operation envelope, specifically a requirement for different operating elevations, power generation flows, and outflows:

$${Γ}_{k \times t} = ( \begin{matrix}{φ}_{𝓏 , 1} & {φ}_{𝓏 , 2} & {φ}_{𝓏 , 3} & ⋯ & {φ}_{𝓏 , t} \\ {φ}_{q − power , 1} & {φ}_{q − power , 2} & {φ}_{q − power , 3} & ⋯ & {φ}_{q − power , t} \\ {φ}_{q − out , 1} & {φ}_{q − out , 2} & {φ}_{q − out , 3} & ⋯ & {φ}_{q − out , t} \\ ⋯ & ⋯ & ⋯ & ⋯ & ⋯ \\ {φ}_{k , 1} & {φ}_{k , 2} & {φ}_{k , 3} & ⋯ & {φ}_{k , t}\end{matrix} ) ;$$

where, Γ denotes a reservoir operation boundary vector, representing an operating envelope characterizing different parameters at different times; k denotes a parameter; ϕ_{z,t} denotes a constraint value for a reservoir elevation at the time t; ϕ_{q-power,t} denotes a constraint value for a reservoir power generation flow at the time t; ϕ_{q-out,t} denotes a constraint value for a reservoir outflow at the time t; and ϕ_{k,t} denotes a constraint value for a k-th parameter at the time t;
S32: performing semantic representation of a reservoir operation boundary condition through a computer language;
S33: performing an operation scenario analysis for a main reservoir function through clustering, classification, and parallel analysis within a permissible reservoir operation range, and forming an operation scenario library:

$$Obj = f ( {x}_{1} , {x}_{2} , {x}_{n} , … , {x}_{n} ) ;$$

where, Obj denotes a main reservoir operation objective; f(□) denotes an operation objective calculation equation; and xₙ denotes a main factor for influencing and evaluating the operation objective; and
S34: calculating an information gain for different operation objectives based on different operation scenarios; determining contributions of different operation requirements under different objective orientations and different operation scenarios; and selecting an optimal feature as a reservoir operation process, thereby completing computations of current reservoir elevation and outflow processes;
where, the information gain is calculated as follows:

$$P ( D ) = - {\sum }_{j = 1}^{J} \frac{\vert {C}_{j} \vert}{\vert D \vert} log \frac{\vert {C}_{j} \vert}{\vert D \vert} ;$$

$$P ( D \vert A ) = {\sum }_{m = 1}^{M} \frac{\vert {D}_{m} \vert}{\vert D \vert} P ( D ) = - {\sum }_{m = 1}^{M} \frac{\vert {D}_{m} \vert}{\vert D \vert} {\sum }_{j = 1}^{J} \frac{\vert {D}_{m j} \vert}{\vert {D}_{m} \vert} log \frac{\vert {D}_{m j} \vert}{\vert {D}_{m} \vert} ;$$

$$FOIL ( S , g ) = P ( D ) - P ( D \vert A ) ;$$

where, P(D) denotes an overall information entropy of a specific operation objective; J denotes classification of different operation scenarios under a same operation objective; j denotes a serial number of a specific operation scenario under the same operation objective, j=1, 2, . . . , J; D denotes a total number of operation scenario samples; Dₘ denotes a total number of samples for a specific operation scenario; Dₘⱼ denotes a number of operation scenario samples for a specific operation objective in a specific operation scenario; Cⱼ denotes a number of operation scenario samples for a specific operation objective; P(D|A) denotes a conditional entropy of an operation scenario A under the same operation objective; and FOIL(S, g) denotes the information gain.

Furthermore, in the step S4, the enabling a dynamic coupled feedback computation between an operation process and flood routing specifically includes:
S41: setting an operation objective for the reservoir in each constituent unit;
S42: sequentially adjusting reservoir operation modes in descending order of the information gains under different operation scenarios for the operation objective, and deriving an operation process for each operation mode;
S43: performing flood routing for upstream and downstream flood wave propagation processes respectively based on the reservoir inflow, outflow and elevation corresponding to the operation process; and
S44: determining whether the flood propagation process aligns with an expected operation objective;
if yes, continuing a computation with a downstream constituent unit; and
if not, adjusting the operation mode, and repeating the step S42 until the flood propagation process aligns with the expected operation objective.

Furthermore, in the step S5, the completing an overall river system computation specifically includes:
S51: sequentially completing, through the steps S41 to S44, the reservoir operation process and upstream and downstream flood routing for each constituent unit; and
S52: sequentially invoking flood wave routing equations along a flow direction; sequentially computing elevations and flows at cross-sections of the constituent units and a river system from upstream to downstream, and obtaining an overall river system routing result for output.

Furthermore, a system for continuous routing forecasting and operation of a cascade reservoir group under influence of river fragmentation includes: at least one processor and a memory communicatively connected to the at least one processor, where
the memory is configured to store an instruction executable by the processor; and the instruction is executed by the processor to implement the method for continuous routing forecasting and operation of a cascade reservoir group under influence of river fragmentation.

The present disclosure has following beneficial effects. The method includes: decomposing and quantitatively characterizing a physical structure of a cascade reservoir system based on an upstream-downstream hydraulic connection and a river channel composition feature, decomposing a fragmented long river system into a river-reservoir system including water channel—reservoir—water channel basic units; generalizing an upstream-downstream relationship of each constituent unit in the system, quantifying a wave characteristic, and establishing upstream and downstream flood routing process equations; and extracting and quantifying an operation rule based on a historical reservoir operation scheme of the constituent unit, enabling a dynamic coupled feedback computation between an operation process and flood routing under different operation modes, and connecting the constituent units sequentially to complete continuous routing of the fragmented long river system. The present disclosure can scientifically analyze the structure of the cascade reservoir group system, quantify the flood routing process under the influence of reservoir operation, and achieve continuous automatic routing for the fragmented long river system. Therefore, the present disclosure provides important technical support for rapid and accurate flood forecasting for basins affected by water engineering.

### BRIEF DESCRIPTION OF THE DRAWINGS

FIG. 1 is a flowchart of a method for continuous routing forecasting and operation of a cascade reservoir group under influence of river fragmentation;

FIG. 2 is a schematic structural diagram of a Lower Jinsha River and Three Gorges cascade reservoir group system in an embodiment;

FIG. 3 is a schematic structural diagram of a basic unit in a river-reservoir system in an embodiment;

FIG. 4 is a schematic diagram of a reservoir operation process for Unit 1 in an embodiment;

FIG. 5 is a schematic diagram of a reservoir operation process for Unit 2 in an embodiment;

FIG. 6 is a schematic diagram of a reservoir operation process for Unit 3 in an embodiment;

FIG. 7 is a schematic diagram of a reservoir operation process for Unit 4 in an embodiment; and

FIG. 8 is a schematic diagram of a reservoir operation process for Unit 5 in an embodiment.

### DETAILED DESCRIPTION OF THE EMBODIMENTS

To make the objectives, technical solutions, and advantages of the present disclosure clearer, the following describes the present disclosure in more detail with reference to the accompanying drawings. It should be understood that the specific embodiments described herein are merely intended to explain the present disclosure, but not to limit the present disclosure.

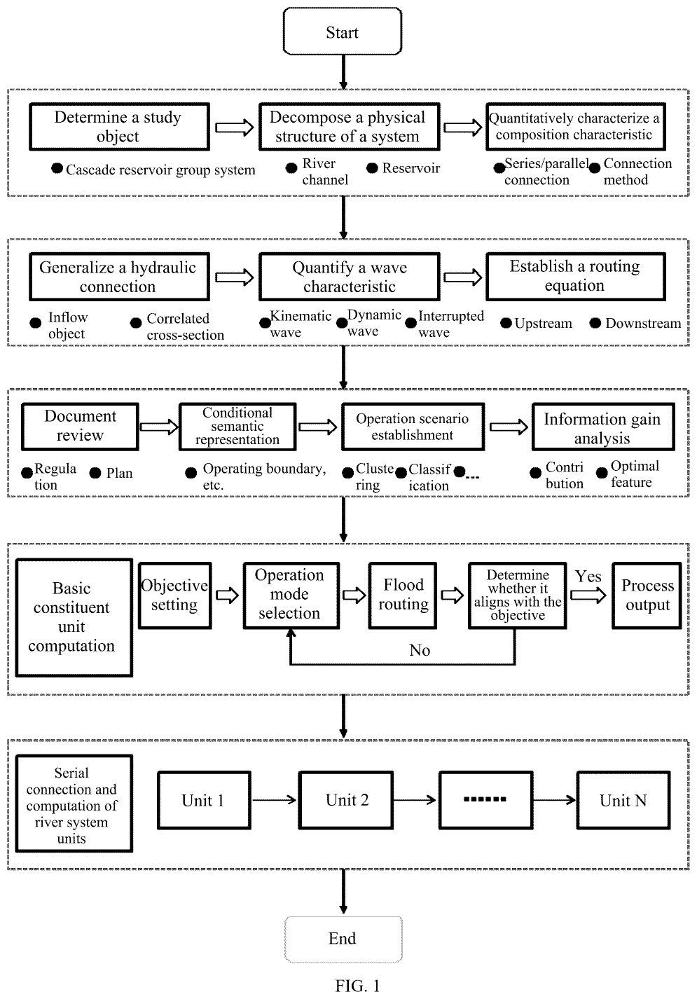

Please refer to FIG. 1. A method for continuous routing forecasting and operation of a cascade reservoir group under influence of river fragmentation includes following steps.

S1. A physical structure of a cascade reservoir group system is decomposed, and a composition characteristic of a river-reservoir system is quantitatively characterized as follows:

$$R = \{ {r}_{1} , {r}_{2} , {r}_{3} , … , {r}_{i} , … , {r}_{N} \} ;$$

where, R denotes the river-reservoir system; rᵢ denotes an i-th basic constituent unit of the system, and is a multi-dimensional vector for characterizing a location of the basic constituent unit, a number of upstream and downstream units, and an operation rule, with a number of dimensions determined by a specific number of characterizing factors; i denotes a serial number of the basic constituent unit of the system, i=1, 2, . . . , N; and N denotes a number of basic constituent units, specifically a number of river channel—reservoir—river channel basic units composing the system;
S2. Based on the composition characteristic of the river-reservoir system, an upstream-downstream hydraulic connection of each constituent unit is generalized, a wave characteristic is quantified, and \ upstream and downstream flood routing process equations are established, respectively:

$${Inf}_{i}^{t} = {q}_{1}^{t} + {q}_{2}^{t} + … + {q}_{M}^{t} ;$$

$${q}_{m}^{t} = f ( {q}_{m , out}^{t} , Δ {q}_{m , E}^{t} ) = w {(}_{m \to i}^{t} ) ;$$

where,

$${Inf}_{i}^{t}$$

denotes a reservoir inflow for the i-th basic constituent unit of the system at time t, m³/s;

$${q}_{m}^{t}$$

denotes an inflow from an m-th upstream unit to the i-th basic constituent unit of the system at the time t, m³/s, m=1, 2, . . . , M;

$${q}_{m , o u t}^{t}$$

denotes a reservoir outflow from the m-th upstream unit at the time t, m³/s;

$$Δ {q}_{m , E}^{t}$$

denotes a flow influence at a unit reservoir cross-section at the time t after the reservoir outflow from the m-th upstream unit routes through a river channel and combines with a lateral inflow, m³/s; and

$$w {(}_{m \to i}^{t} )$$

denotes a flood routing process equation incorporating a basic wave characteristic, with a calculation result representing an inflow propagating to a reservoir of the i-th basic constituent unit of the system at the time t after the reservoir outflow from the m-th upstream unit combines with the lateral inflow.

S3. A reservoir operation rule for each constituent unit is quantified.

S4. A reservoir operation mode is adjusted according to an operation objective of the reservoir in each constituent unit, and a dynamic coupled feedback computation between an operation process and flood routing is achieved.

S5. Routing is sequentially completed for each constituent unit, and a serial connection is achieved through the upstream-downstream hydraulic connection and the routing process equation, thereby completing an overall river system computation.

In the step S1, the composition characteristic of the river-reservoir system refers to a series/parallel relationship and a connection method of the river channel—reservoir—river channel basic constituent units; the series/parallel relationship includes three types: series, parallel, and hybrid; and the connection method includes a head-to-tail connection and a connection via a natural river channel between an upstream basic constituent unit and a downstream basic constituent unit.

In the step S2, the wave characteristic includes kinematic wave, diffusive wave, inertial wave, dynamic wave, and interrupted wave; based on an occurrence frequency and an influence proportion, an upstream wave characteristic includes three types: kinematic wave, dynamic wave, and hybrid wave; and a downstream wave characteristic includes three types: kinematic wave, dynamic wave, and interrupted wave.

In the step S3, the reservoir operation rule is quantified as follows.

S31. A requirement of an existing reservoir operation regulation and operation plan is organized and analyzed, basic reservoir information is combined with a characteristic parameter, and a reservoir operation envelope is determined, specifically a requirement for different operating elevations, power generation flows, and outflows:

$${Γ}_{k \times t} = ( \begin{matrix}{φ}_{z , 1} & {φ}_{z , 2} & {φ}_{z , 3} & … & {φ}_{z , t} \\ {φ}_{q - power , 1} & {φ}_{q - power , 2} & {φ}_{q - power , 3} & … & {φ}_{q - power , t} \\ {φ}_{q - out , 1} & {φ}_{q - out , 2} & {φ}_{q - out , 3} & … & {φ}_{q - out , t} \\ … & … & … & … & … \\ {φ}_{k , 1} & {φ}_{k , 2} & {φ}_{k , 3} & … & {φ}_{k , t}\end{matrix} ) ;$$

where, Γ denotes a reservoir operation boundary vector, representing an operating envelope characterizing different parameters at different times; k denotes a parameter; ϕ_{z,t} denotes a constraint value for a reservoir elevation at the time t; ϕ_{q-power,t} denotes a constraint value for a reservoir power generation flow at the time t; ϕ_{q-out,t} denotes a constraint value for a reservoir outflow at the time t; and ϕ_{k,t} denotes a constraint value for a k-th parameter at the time t.

S32. Semantic representation of a reservoir operation boundary condition is performed through a computer language.

S33. An operation scenario analysis is performed for a main reservoir function through clustering, classification, and parallel analysis within a permissible reservoir operation range, and an operation scenario library is formed:

$$Obj = f ( {x}_{1} , {x}_{2} , … , {x}_{n} ) ;$$

where, Obj denotes a main reservoir operation objective; f(□) denotes an operation objective calculation equation; and xₙ denotes a main factor for influencing and evaluating the operation objective.

S34. An information gain is calculated for different operation objectives based on different operation scenarios, contributions of different operation requirements under different objective orientations and different operation scenarios are determined, and an optimal feature is selected as a reservoir operation process, thereby completing computations of current reservoir elevation and outflow processes.

The information gain is calculated as follows:

$$P ( D ) = - {\sum }_{j = 1}^{J} \frac{\vert {C}_{j} \vert}{\vert D \vert} log \frac{\vert {C}_{j} \vert}{\vert D \vert} ;$$

$$P ( D \vert A ) = {\sum }_{m = 1}^{M} \frac{\vert {D}_{m} \vert}{\vert D \vert} P ( D ) = - {\sum }_{m = 1}^{M} \frac{\vert {D}_{m} \vert}{\vert D \vert} {\sum }_{j = 1}^{J} \frac{\vert {D}_{mj} \vert}{\vert {D}_{m} \vert} log \frac{\vert {D}_{mj} \vert}{\vert {D}_{m} \vert} ;$$

$$FOIL ( S , g ) = P ( D ) - P ( D \vert A ) ;$$

where, P(D) denotes an overall information entropy of a specific operation objective; J denotes classification of different operation scenarios under a same operation objective; j denotes a serial number of a specific operation scenario under the same operation objective, j=1, 2, . . . , J; D denotes a total number of operation scenario samples; Dₘ denotes a total number of samples for a specific operation scenario; Dₘⱼ denotes a number of operation scenario samples for a specific operation objective in a specific operation scenario; Cⱼ denotes a number of operation scenario samples for a specific operation objective; P(D|A) denotes a conditional entropy of operation scenario A under the same operation objective; and FOIL(S, g) denotes the information gain.

In the step S4, the dynamic coupled feedback computation between an operation process and flood routing is specifically achieved as follows.

S41. An operation objective is set for the reservoir in each constituent unit.

S42. Reservoir operation modes are sequentially adjusted in descending order of the information gains under different operation scenarios for the operation objective, and an operation process is derived for each operation mode.

S43. Flood routing is performed for upstream and downstream flood wave propagation processes respectively based on the reservoir inflow, outflow and elevation corresponding to the operation process.

S44. It is determined whether the flood propagation process aligns with an expected operation objective.

If yes, a computation with a downstream constituent unit is continued.

If not, the operation mode is adjusted, and the step S42 is repeated until the flood propagation process aligns with the expected operation objective.

In the step S5, the overall river system computation is specifically completed as follows.

S51. The reservoir operation process and upstream and downstream flood routing are sequentially completed through the steps S41 to S44 for each constituent unit.

S52. A flood wave routing equation is sequentially invoked along a flow direction, elevations and flows at cross-sections of the constituent units and a river system are sequentially computed from upstream to downstream, and an overall river system routing result is obtained for output.

The present disclosure further provides a system for continuous routing forecasting and operation of a cascade reservoir group under influence of river fragmentation includes: at least one processor and a memory communicatively connected to the at least one processor, where the memory is configured to store an instruction executable by the processor; and the instruction is executed by the processor to implement the method for continuous routing forecasting and operation of a cascade reservoir group under influence of river fragmentation.

Taking a Lower Jinsha River and Three Gorges cascade reservoir group system in the upper Yangtze River as an example, a continuous routing for river system flood forecasting and operation was conducted to verify the feasibility and effectiveness of the method of the present disclosure.

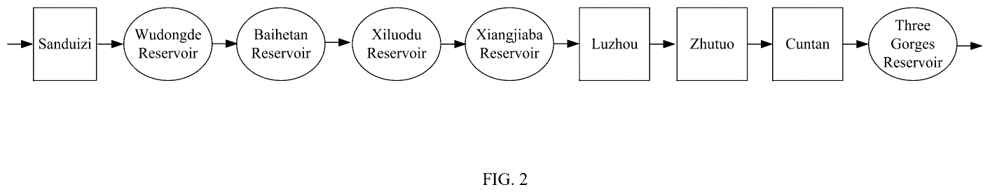

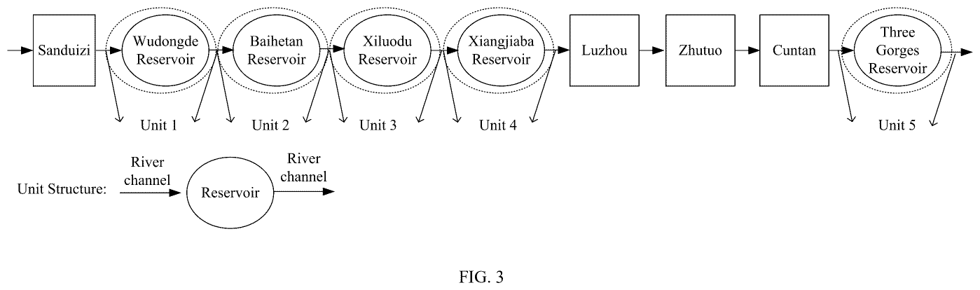

FIG. 1 characterizes the Lower Jinsha River and Three Gorges cascade reservoir group system, a fragmented river system in the upper Yangtze River. As seen in FIG. 2 and FIG. 3, the study object in the embodiment is decomposed into 5 river channel—reservoir—river channel basic constituent units. Unit 2 and Unit 3, as well as and Unit 3 and Unit 4 exhibit different connection methods under different reservoir elevations and flow magnitudes. For example, for Unit 2 and Unit 3, when the elevation of the Xiluodu Reservoir in Unit 3 is high, it connects head-to-tail with Unit 2, whereas when the elevation is low, it is connected by a natural river channel. In Unit 5, the upstream and downstream positions of the Three Gorges Reservoir exhibit different flood wave characteristics under different elevations, different flow magnitudes, and different operation processes.

When a flood event occurs and the cascade reservoir group system executes flood control operation objectives, the method of the present disclosure is utilized to implement forecast and operation calculations sequentially for each basic constituent unit from upstream to downstream along the flow direction. The continuous calculation results for the Lower Jinsha River and Three Gorges cascade reservoir group system are obtained.

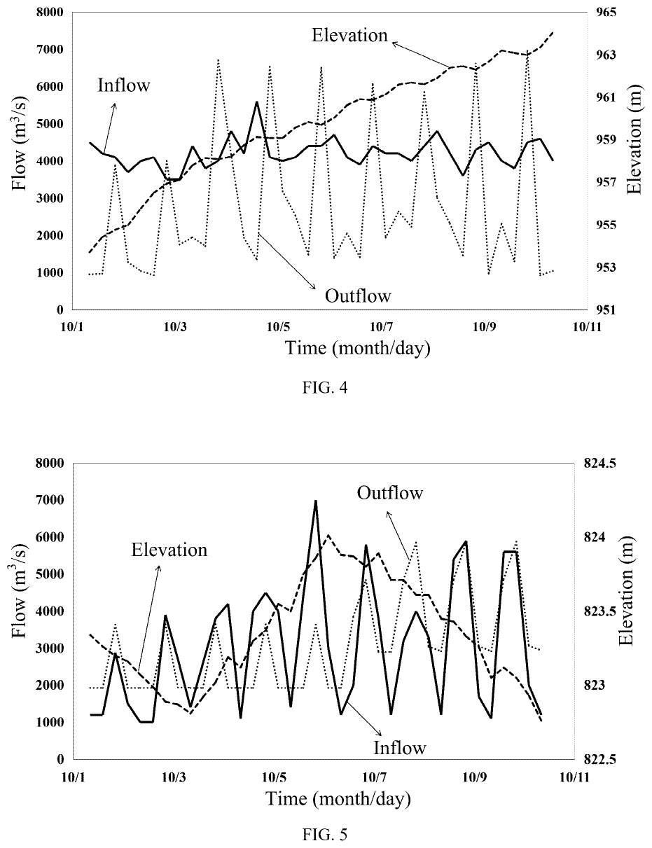

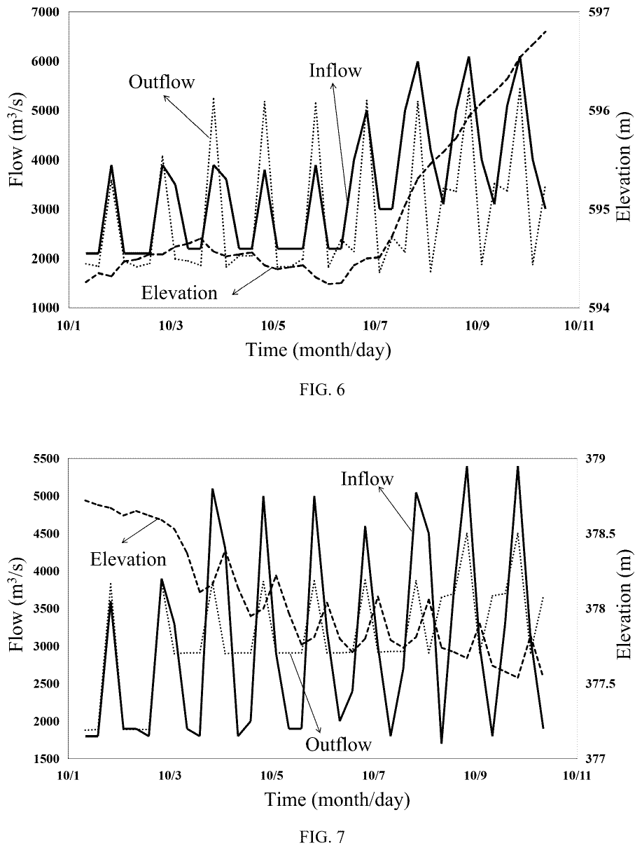

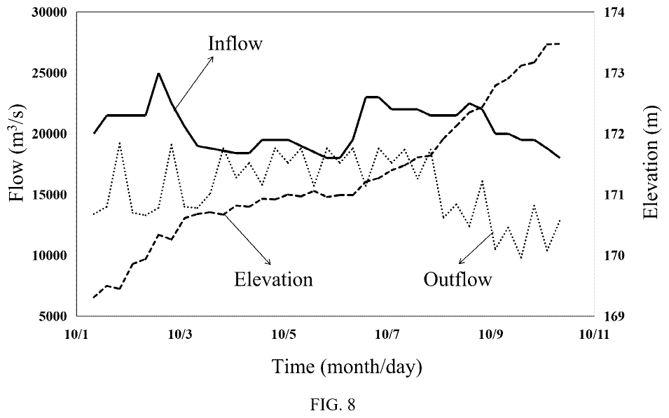

The specific operation processes of the reservoirs in each basic constituent unit, as shown in Table 1 and Table 8, are characterized in FIGS. 4 to 8. In the table, the reservoir elevation is in meters (m), while the inflow and outflow are in cubic meters per second (m³/s).

TABLE 1
Specific Operation Process Information Table for Units 1 to 3

| | | Unit 1 - reservoir | | | Unit 2 - reservoir | | | Unit 3 - reservoir | | |
|---|---|---|---|---|---|---|---|---|---|---|
| SN | Time | Elevation | Inflow | Outflow | Elevation | Inflow | Outflow | Elevation | Inflow | Outflow |
| 1 | 2023 Oct. 1 | 953.7 | 4500 | 950 | 823.34 | 1200 | 1930 | 594.26 | 2100 | 1890 |
| | 8:00 | | | | | | | | | |
| 2 | 2023 Oct. 1 | 954.42 | 4200 | 968 | 823.26 | 1200 | 1930 | 594.35 | 2100 | 1840 |
| | 14:00 | | | | | | | | | |
| 3 | 2023 Oct. 1 | 954.76 | 4100 | 3880 | 823.2 | 2880 | 3640 | 594.32 | 3900 | 3580 |
| | 20:00 | | | | | | | | | |
| 4 | 2023 Oct. 2 | 954.98 | 3700 | 1280 | 823.16 | 1500 | 1930 | 594.47 | 2100 | 1950 |
| | 2:00 | | | | | | | | | |
| 5 | 2023 Oct. 2 | 955.77 | 4000 | 1040 | 823.07 | 1000 | 1930 | 594.49 | 2100 | 1830 |
| | 8:00 | | | | | | | | | |
| 6 | 2023 Oct. 2 | 956.5 | 4100 | 927 | 822.99 | 1000 | 1930 | 594.54 | 2100 | 1900 |
| | 14:00 | | | | | | | | | |
| 7 | 2023 Oct. 2 | 956.93 | 3500 | 4000 | 822.89 | 3900 | 3650 | 594.54 | 3900 | 4070 |
| | 20:00 | | | | | | | | | |
| 8 | 2023 Oct. 3 | 957.1 | 3500 | 1750 | 822.87 | 2700 | 1940 | 594.62 | 3500 | 1990 |
| | 2:00 | | | | | | | | | |
| 9 | 2023 Oct. 3 | 957.79 | 4400 | 1950 | 822.81 | 1400 | 1930 | 594.65 | 2200 | 1950 |
| | 8:00 | | | | | | | | | |
| 10 | 2023 Oct. 3 | 958.14 | 3800 | 1710 | 822.92 | 2600 | 1930 | 594.7 | 2200 | 1860 |
| | 14:00 | | | | | | | | | |

TABLE 2
Specific Operation Process Information Table for Units 1 to 3

| | | Unit 1 - reservoir | | | Unit 2 - reservoir | | | Unit 3 - reservoir | | |
|---|---|---|---|---|---|---|---|---|---|---|
| SN | Time | Elevation | Inflow | Outflow | Elevation | Inflow | Outflow | Elevation | Inflow | Outflow |
| 11 | 2023 Oct. 3 | 958.08 | 4000 | 6710 | 823.02 | 3800 | 3650 | 594.57 | 3900 | 5240 |
| | 20:00 | | | | | | | | | |
| 12 | 2023 Oct. 4 | 958.2 | 4800 | 4170 | 823.19 | 4200 | 1930 | 594.52 | 3600 | 1830 |
| | 2:00 | | | | | | | | | |
| 13 | 2023 Oct. 4 | 958.74 | 4200 | 1930 | 823.12 | 1100 | 1930 | 594.54 | 2200 | 2050 |
| | 8:00 | | | | | | | | | |
| 14 | 2023 Oct. 4 | 959.13 | 5600 | 1350 | 823.3 | 4000 | 1930 | 594.56 | 2200 | 2050 |
| | 14:00 | | | | | | | | | |
| 15 | 2023 Oct. 4 | 959.08 | 4100 | 6530 | 823.37 | 4500 | 3650 | 594.43 | 3800 | 5180 |
| | 20:00 | | | | | | | | | |
| 16 | 2023 Oct. 5 | 959.08 | 4000 | 3180 | 823.55 | 4000 | 1930 | 594.39 | 2200 | 1830 |
| | 2:00 | | | | | | | | | |
| 17 | 2023 Oct. 5 | 959.57 | 4100 | 2530 | 823.5 | 1400 | 1930 | 594.41 | 2200 | 1830 |
| | 8:00 | | | | | | | | | |
| 18 | 2023 Oct. 5 | 959.83 | 4400 | 1480 | 823.75 | 4400 | 1930 | 594.43 | 2200 | 1990 |
| | 14:00 | | | | | | | | | |
| 19 | 2023 Oct. 5 | 959.7 | 4400 | 6510 | 823.86 | 7000 | 3640 | 594.31 | 3900 | 5150 |
| | 20:00 | | | | | | | | | |
| 20 | 2023 Oct. 6 | 960.02 | 4700 | 1390 | 824.01 | 3000 | 1930 | 594.24 | 2200 | 1830 |
| | 2:00 | | | | | | | | | |

TABLE 3
Specific Operation Process Information Table for Units 1 to 3

| | | Unit 1 - reservoir | | | Unit 2 - reservoir | | | Unit 3 - reservoir | | |
|---|---|---|---|---|---|---|---|---|---|---|
| SN | Time | Elevation | Inflow | Outflow | Elevation | Inflow | Outflow | Elevation | Inflow | Outflow |
| 21 | 2023 Oct. 6 | 960.62 | 4100 | 2060 | 823.88 | 1200 | 1930 | 594.25 | 2200 | 2380 |
| | 8:00 | | | | | | | | | |
| 22 | 2023 Oct. 6 | 960.9 | 3900 | 1410 | 823.87 | 2000 | 3860 | 594.43 | 4000 | 2140 |
| | 14:00 | | | | | | | | | |
| 23 | 2023 Oct. 6 | 960.86 | 4400 | 6060 | 823.8 | 5800 | 4840 | 594.5 | 5000 | 5200 |
| | 20:00 | | | | | | | | | |
| 24 | 2023 Oct. 7 | 961.13 | 4200 | 1940 | 823.89 | 3800 | 2900 | 594.51 | 3000 | 1720 |
| | 2:00 | | | | | | | | | |
| 25 | 2023 Oct. 7 | 961.58 | 4200 | 2640 | 823.71 | 1200 | 2900 | 594.73 | 3000 | 2430 |
| | 8:00 | | | | | | | | | |
| 26 | 2023 Oct. 7 | 961.68 | 4000 | 2230 | 823.71 | 3200 | 4840 | 595.04 | 5000 | 2130 |
| | 14:00 | | | | | | | | | |
| 27 | 2023 Oct. 7 | 961.6 | 4400 | 5850 | 823.61 | 4000 | 5850 | 595.31 | 6000 | 5180 |
| | 20:00 | | | | | | | | | |
| 28 | 2023 Oct. 8 | 961.9 | 4800 | 3000 | 823.61 | 3300 | 3040 | 595.46 | 4200 | 1730 |
| | 2:00 | | | | | | | | | |
| 29 | 2023 Oct. 8 | 962.38 | 4200 | 2310 | 823.45 | 1200 | 2920 | 595.58 | 3100 | 3420 |
| | 8:00 | | | | | | | | | |
| 30 | 2023 Oct. 8 | 962.45 | 3600 | 1460 | 823.43 | 5400 | 4860 | 595.72 | 5000 | 3360 |
| | 14:00 | | | | | | | | | |

TABLE 4
Specific Operation Process Information Table for Units 1 to 3

| | | Unit 1 - reservoir | | | Unit 2 - reservoir | | | Unit 3 - reservoir | | |
|---|---|---|---|---|---|---|---|---|---|---|
| SN | Time | Elevation | Inflow | Outflow | Elevation | Inflow | Outflow | Elevation | Inflow | Outflow |
| 31 | 2023 Oct. 8 | 962.29 | 4300 | 6620 | 823.33 | 5900 | 5860 | 595.94 | 6100 | 5450 |
| | 20:00 | | | | | | | | | |
| 32 | 2023 Oct. 9 | 962.67 | 4500 | 968 | 823.26 | 1700 | 3050 | 596.08 | 4000 | 1880 |
| | 2:00 | | | | | | | | | |
| 33 | 2023 Oct. 9 | 963.19 | 4000 | 2310 | 823.05 | 1100 | 2920 | 596.19 | 3100 | 3520 |
| | 8:00 | | | | | | | | | |
| 34 | 2023 Oct. 9 | 963.07 | 3800 | 1300 | 823.12 | 5600 | 4870 | 596.32 | 5100 | 3370 |
| | 14:00 | | | | | | | | | |
| 35 | 2023 Oct. 9 | 962.97 | 4500 | 6960 | 823.05 | 5600 | 5880 | 596.54 | 6100 | 5440 |
| | 20:00 | | | | | | | | | |
| 36 | 2023 Oct. 10 | 963.34 | 4600 | 921 | 822.93 | 2000 | 3060 | 596.67 | 4000 | 1880 |
| | 2:00 | | | | | | | | | |
| 37 | 2023 Oct. 10 | 964.05 | 4000 | 1050 | 822.76 | 1200 | 2940 | 596.8 | 3000 | 3510 |
| | 8:00 | | | | | | | | | |

TABLE 5
Specific Operation Process Information Table for Units 4 to 5

| | | Unit 4 - reservoir | | | Unit 5 - reservoir | | |
|---|---|---|---|---|---|---|---|
| | | Eleva- | In- | Out- | Eleva- | In- | Out- |
| SN | Time | tion | flow | flow | tion | flow | flow |
| 1 | 2023 Oct. 1 | 378.72 | 1800 | 1880 | 169.31 | 20000 | 13400 |
| | 8:00 | | | | | | |
| 2 | 2023 Oct. 1 | 378.69 | 1800 | 1890 | 169.5 | 21500 | 14000 |
| | 14:00 | | | | | | |
| 3 | 2023 Oct. 1 | 378.67 | 3600 | 3830 | 169.45 | 21500 | 19200 |
| | 20:00 | | | | | | |
| 4 | 2023 Oct. 2 | 378.62 | 1900 | 1890 | 169.86 | 21500 | 13500 |
| | 2:00 | | | | | | |
| 5 | 2023 Oct. 2 | 378.65 | 1900 | 1890 | 169.94 | 21500 | 13300 |
| | 8:00 | | | | | | |
| 6 | 2023 Oct. 2 | 378.62 | 1800 | 1890 | 170.34 | 25000 | 13900 |
| | 14:00 | | | | | | |
| 7 | 2023 Oct. 2 | 378.59 | 3900 | 3850 | 170.26 | 22500 | 19100 |
| | 20:00 | | | | | | |
| 8 | 2023 Oct. 3 | 378.53 | 3300 | 2900 | 170.61 | 20600 | 14000 |
| | 2:00 | | | | | | |
| 9 | 2023 Oct. 3 | 378.37 | 1900 | 2910 | 170.68 | 19000 | 13900 |
| | 8:00 | | | | | | |
| 10 | 2023 Oct. 3 | 378.11 | 1800 | 2910 | 170.71 | 18800 | 15100 |
| | 14:00 | | | | | | |

TABLE 6
Specific Operation Process Information Table for Units 4 to 5

| | | Unit 4 - reservoir | | | Unit 5 - reservoir | | |
|---|---|---|---|---|---|---|---|
| | | Eleva- | In- | Out- | Eleva- | In- | Out- |
| SN | Time | tion | flow | flow | tion | flow | flow |
| 11 | 2023 Oct. 3 | 378.16 | 5100 | 3850 | 170.67 | 18600 | 18800 |
| | 20:00 | | | | | | |
| 12 | 2023 Oct. 4 | 378.39 | 4300 | 2900 | 170.82 | 18400 | 16400 |
| | 2:00 | | | | | | |
| 13 | 2023 Oct. 4 | 378.14 | 1800 | 2910 | 170.8 | 18400 | 17600 |
| | 8:00 | | | | | | |
| 14 | 2023 Oct. 4 | 377.95 | 2000 | 2910 | 170.93 | 19500 | 15800 |
| | 14:00 | | | | | | |
| 15 | 2023 Oct. 4 | 378 | 5000 | 3860 | 170.92 | 19500 | 18800 |
| | 20:00 | | | | | | |
| 16 | 2023 Oct. 5 | 378.22 | 2900 | 2910 | 171 | 19500 | 17600 |
| | 2:00 | | | | | | |
| 17 | 2023 Oct. 5 | 377.97 | 1900 | 2910 | 170.97 | 19000 | 18800 |
| | 8:00 | | | | | | |
| 18 | 2023 Oct. 5 | 377.76 | 1900 | 2910 | 171.06 | 18500 | 15700 |
| | 14:00 | | | | | | |
| 19 | 2023 Oct. 5 | 377.81 | 5000 | 3870 | 170.96 | 18000 | 18800 |
| | 20:00 | | | | | | |
| 20 | 2023 Oct. 6 | 378.04 | 3200 | 2910 | 170.99 | 18000 | 17600 |
| | 2:00 | | | | | | |

TABLE 7
Specific Operation Process Information Table for Units 4 to 5

| | | Unit 4 - reservoir | | | Unit 5 - reservoir | | |
|---|---|---|---|---|---|---|---|
| | | Eleva- | In- | Out- | Eleva- | In- | Out- |
| SN | Time | tion | flow | flow | tion | flow | flow |
| 21 | 2023 Oct. 6 | 377.8 | 2000 | 2910 | 170.99 | 19500 | 18800 |
| | 8:00 | | | | | | |
| 22 | 2023 Oct. 6 | 377.71 | 2400 | 2920 | 171.21 | 23000 | 15700 |
| | 14:00 | | | | | | |
| 23 | 2023 Oct. 6 | 377.8 | 4600 | 3880 | 171.27 | 23000 | 18800 |
| | 20:00 | | | | | | |
| 24 | 2023 Oct. 7 | 378.08 | 3000 | 2920 | 171.4 | 22000 | 17600 |
| | 2:00 | | | | | | |
| 25 | 2023 Oct. 7 | 377.79 | 1800 | 2930 | 171.48 | 22000 | 18700 |
| | 8:00 | | | | | | |
| 26 | 2023 Oct. 7 | 377.74 | 2700 | 2930 | 171.61 | 22000 | 16300 |
| | 14:00 | | | | | | |
| 27 | 2023 Oct. 7 | 377.81 | 5050 | 3870 | 171.64 | 21500 | 18700 |
| | 20:00 | | | | | | |
| 28 | 2023 Oct. 8 | 378.06 | 4500 | 2910 | 171.92 | 21500 | 13100 |
| | 2:00 | | | | | | |
| 29 | 2023 Oct. 8 | 377.74 | 1700 | 3650 | 172.13 | 21500 | 14200 |
| | 8:00 | | | | | | |
| 30 | 2023 Oct. 8 | 377.71 | 3800 | 3700 | 172.35 | 22500 | 12400 |
| | 14:00 | | | | | | |

TABLE 8
Specific Operation Process Information Table for Units 4 to 5

| | | Unit 4 - reservoir | | | Unit 5 - reservoir | | |
|---|---|---|---|---|---|---|---|
| | | Eleva- | In- | Out- | Eleva- | In- | Out- |
| SN | Time | tion | flow | flow | tion | flow | flow |
| 31 | 2023 Oct. 8 | 377.67 | 5400 | 4500 | 172.44 | 22000 | 16100 |
| | 20:00 | | | | | | |
| 32 | 2023 Oct. 9 | 377.9 | 3000 | 2910 | 172.79 | 20000 | 10500 |
| | 2:00 | | | | | | |
| 33 | 2023 Oct. 9 | 377.62 | 1800 | 3670 | 172.91 | 20000 | 12300 |
| | 8:00 | | | | | | |
| 34 | 2023 Oct. 9 | 377.58 | 3300 | 3700 | 173.12 | 19500 | 9810 |
| | 14:00 | | | | | | |
| 35 | 2023 Oct. 9 | 377.54 | 5400 | 4500 | 173.17 | 19500 | 14100 |
| | 20:00 | | | | | | |
| 36 | 2023 Oct. 10 | 377.82 | 3100 | 2910 | 173.47 | 18800 | 10400 |
| | 2:00 | | | | | | |
| 37 | 2023 Oct. 10 | 377.54 | 1900 | 3660 | 173.48 | 18000 | 12900 |
| | 8:00 | | | | | | |

As can be seen from FIGS. 4 to 8, the method of the present disclosure adopts a computational approach involving unit division, wave characteristic quantification, routing equation calculation, and operation rule extraction. This enables rapid implementation of continuous routing, as well as coupled feedback computation between flood propagation and reservoir operation for flood forecasting of the river-reservoir system composed of river channel—reservoir—river channel basic units. By fully considering operation objectives and reservoir operation constraints, the present disclosure obtains the reservoir group forecasting and operation process, demonstrating the feasibility and effectiveness of the method. This indicates that the method has superior application effects in flood forecasting and operation for fragmented long river system basins.

Based on the above analysis, the method of the present disclosure is highly practical and can effectively solve the problem of automatic continuous routing for flood forecasting and operation of rivers under fragmenting conditions caused by reservoir groups.

In summary, the present disclosure has advantages such as strong practicality and operability. It can rapidly achieve automatic continuous routing for fragmented long river systems, and obtain forecasting and operation results for key cross-sections, providing a more scientific and efficient new method for basin hydrological forecasting and reservoir operation.

The above embodiments are merely illustrative of some implementations of the present disclosure, and the description thereof is specific and detailed, but should not be construed as limiting the patent scope of the present disclosure. It should be noted that those of ordinary skill in the art can further make several variations and improvements without departing from the concept of the present disclosure, and all of these fall within the protection scope of the present disclosure. Therefore, the patent protection scope of the present disclosure should be subject to the appended claims.

1. A method for continuous routing forecasting and operation of a reservoir group under an influence of river fragmentation, comprising:
S1: decomposing a physical structure of a cascade reservoir group system, and quantitatively characterizing a composition characteristic of a river-reservoir system as follows:
$$R = ( {r}_{1} , {r}_{2} , {r}_{3} , … , {r}_{i} , … , {r}_{N} ) ;$$
wherein, R denotes the river-reservoir system; rᵢ denotes an i-th basic constituent unit of the river-reservoir system, and is a multi-dimensional vector for characterizing a location of the basic constituent unit, a number of upstream and downstream units, and an operation rule, with a number of dimensions determined by a specific number of characterizing factors; i denotes a serial number of the basic constituent unit of the river-reservoir system, i=1, 2, . . . , N; and N denotes a number of basic constituent units, and is a number of river channel-reservoir-river channel basic units composing the river-reservoir system;
S2: generalizing, based on the composition characteristic of the river-reservoir system, an upstream-downstream hydraulic connection of each constituent unit; quantifying a wave characteristic; and establishing upstream and downstream flood routing process equations, respectively:
$${Inf}_{i}^{t} = {q}_{1}^{t} + {q}_{2}^{t} + … + {q}_{M}^{t} ;$$
$${q}_{m}^{t} = f ( {q}_{m , out}^{t} , Δ {q}_{m , E}^{t} ) = w {(}_{m \to i}^{t} ) ;$$
wherein,
$${Inf}_{i}^{t}$$
denotes a reservoir inflow for the i-th basic constituent unit of the river-reservoir system at a time t, m³/s;
$${q}_{m}^{t}$$
denotes an inflow from an m-th upstream unit to the i-th basic constituent unit of the river-reservoir system at the time t, m³/s, m=1, 2, . . . , M;
$${q}_{m , out}^{t}$$
denotes a reservoir outflow from the m-th upstream unit at the time t, m³/s;
$$Δ {q}_{m , E}^{t}$$
denotes a flow influence at a unit reservoir cross-section at the time t after the reservoir outflow from the m-th upstream unit routes through a river channel and combines with a lateral inflow, m³/s; and
$$w {(}_{m \to i}^{t} )$$
denotes a flood routing process equation incorporating a basic wave characteristic, with a calculation result representing an inflow propagating to a reservoir of the i-th basic constituent unit of the river-reservoir system at the time t after the reservoir outflow from the m-th upstream unit combines with the lateral inflow;
S3: quantifying a reservoir operation rule for each constituent unit;
S4: adjusting a reservoir operation mode according to an operation objective of the reservoir in each constituent unit; and enabling a dynamic coupled feedback computation between an operation process and flood routing; and
S5: sequentially completing routing for each constituent unit; and enabling a serial connection through the upstream-downstream hydraulic connection and the flood routing process equation, thereby completing an overall river system computation;
wherein in the step S3, the quantifying the reservoir operation rule comprises:
S31: organizing and analyzing a requirement of an existing reservoir operation regulation and operation plan, combining basic reservoir information and a characteristic parameter, and determining a reservoir operation envelope, specifically a requirement for different operating elevations, power generation flows, and outflows:
$${Γ}_{k \times t} = ( \begin{matrix}{φ}_{z , 1} & {φ}_{z , 2} & {φ}_{z , 3} & … & {φ}_{z , t} \\ {φ}_{q - power , 1} & {φ}_{q - power , 2} & {φ}_{q - power , 3} & … & {φ}_{q - power , t} \\ {φ}_{q - out , 1} & {φ}_{q - out , 2} & {φ}_{q - out , 3} & … & {φ}_{q - out , t} \\ … & … & … & … & … \\ {φ}_{k , 1} & {φ}_{k , 2} & {φ}_{k , 3} & … & {φ}_{k , t}\end{matrix} ) ;$$
wherein, Γ denotes a reservoir operation boundary vector, representing an operating envelope characterizing different parameters at different times; k denotes a parameter; ϕ_{z,t} denotes a constraint value for a reservoir elevation at the time t; ϕ_{q-power,t} denotes a constraint value for a reservoir power generation flow at the time t; ϕ_{q-out,t} denotes a constraint value for a reservoir outflow at the time t; and ϕ_{k,t} denotes a constraint value for a k-th parameter at the time t;
S32: performing semantic representation of a reservoir operation boundary condition through a computer language;
S33: performing an operation scenario analysis for a main reservoir function through clustering, classification, and parallel analysis within a permissible reservoir operation range, and forming an operation scenario library:
$$Obj = f ( {x}_{1} , {x}_{2} , … , {x}_{n} ) ;$$
wherein, Obj denotes a main reservoir operation objective; f(□) denotes an operation objective calculation equation; and xₙ denotes a main factor for influencing and evaluating the main reservoir operation objective; and
S34: calculating an information gain for different operation objectives based on different operation scenarios; determining contributions of different operation requirements under different objective orientations and different operation scenarios; and selecting an optimal feature as a reservoir operation process, thereby completing computations of current reservoir elevation and outflow processes;
wherein, the information gain is calculated as follows:
$$P ( D ) = - {\sum }_{j = 1}^{J} \frac{\vert {C}_{j} \vert}{\vert D \vert} log \frac{\vert {C}_{j} \vert}{\vert D \vert} ;$$
$$P ( D \vert A ) = {\sum }_{m = 1}^{M} \frac{\vert {D}_{m} \vert}{\vert D \vert} P ( D ) = - {\sum }_{m = 1}^{M} \frac{\vert {D}_{m} \vert}{\vert D \vert} {\sum }_{j = 1}^{J} \frac{\vert {D}_{mj} \vert}{\vert {D}_{m} \vert} log \frac{\vert {D}_{mj} \vert}{\vert {D}_{m} \vert} ;$$
$$FOIL ( S , g ) = P ( D ) - P ( D \vert A ) ;$$
wherein, P(D) denotes an overall information entropy of a specific operation objective; J denotes classification of different operation scenarios under a same operation objective; J denotes a serial number of a specific operation scenario under the same operation objective, j=1, 2, J; D denotes a total number of operation scenario samples; Dₘ denotes a total number of samples for a specific operation scenario; Dₘⱼ denotes a number of operation scenario samples for a specific operation objective in a specific operation scenario; Cⱼ denotes a number of operation scenario samples for a specific operation objective; P(D|A) denotes a conditional entropy of an operation scenario A under the same operation objective; and FOIL(S, g) denotes the information gain.

2. The method for continuous routing forecasting and operation of the reservoir group under the influence of river fragmentation according to claim 1, wherein in the step S1, the composition characteristic of the river-reservoir system refers to a series/parallel relationship and a connection method of the river channel—reservoir—river channel basic constituent units; the series/parallel relationship comprises three types: series, parallel, and hybrid; and the connection method comprises a head-to-tail connection and a connection via a natural river channel between an upstream basic constituent unit and a downstream basic constituent unit.

3. The method for continuous routing forecasting and operation of the reservoir group under the influence of river fragmentation according to claim 2, wherein in the step S2, the wave characteristic comprises kinematic wave, diffusive wave, inertial wave, dynamic wave, and interrupted wave; based on an occurrence frequency and an influence proportion, an upstream wave characteristic comprises kinematic wave, dynamic wave, and hybrid wave; and a downstream wave characteristic comprises kinematic wave, dynamic wave, and interrupted wave.

4. The method for continuous routing forecasting and operation of the reservoir group under the influence of river fragmentation according to claim 3, wherein in the step S4, the enabling the dynamic coupled feedback computation between the operation process and the flood routing comprises:
S41: setting an operation objective for the reservoir in each constituent unit;
S42: sequentially adjusting reservoir operation modes in descending order of the information gains under different operation scenarios for the operation objective, and deriving an operation process for each operation mode;
S43: performing flood routing for upstream and downstream flood wave propagation processes respectively based on the reservoir inflow, outflow and elevation corresponding to the operation process; and
S44: determining whether the flood propagation process aligns with an expected operation objective;
if yes, continuing a computation with a downstream constituent unit; and
if not, adjusting the operation mode, and repeating the step S42 until the flood propagation process aligns with the expected operation objective.

5. The method for continuous routing forecasting and operation of the reservoir group under the influence of river fragmentation according to claim 4, wherein in the step S5, the completing the overall river system computation comprises:
S51: sequentially completing, through the steps S41 to S44, the reservoir operation process and upstream and downstream flood routing for each constituent unit; and
S52: sequentially invoking flood wave routing equations along a flow direction; sequentially computing elevations and flows at cross-sections of the constituent units and a river system from upstream to downstream, and obtaining an overall river system routing result for output.

6. A system for continuous routing forecasting and operation of a reservoir group under an influence of river fragmentation, comprising: at least one processor and a memory communicatively connected to the at least one processor, wherein
the memory is configured to store an instruction executable by the at least one processor; and the instruction is executed by the at least one processor to implement the method for continuous routing forecasting and operation of the reservoir group under the influence of river fragmentation according to claim 1.

7. The system for continuous routing forecasting and operation of the reservoir group under the influence of river fragmentation according to claim 6, wherein in the step S1, the composition characteristic of the river-reservoir system refers to a series/parallel relationship and a connection method of the river channel—reservoir—river channel basic constituent units; the series/parallel relationship comprises three types: series, parallel, and hybrid; and the connection method comprises a head-to-tail connection and a connection via a natural river channel between an upstream basic constituent unit and a downstream basic constituent unit.

8. The system for continuous routing forecasting and operation of the reservoir group under the influence of river fragmentation according to claim 7, wherein in the step S2, the wave characteristic comprises kinematic wave, diffusive wave, inertial wave, dynamic wave, and interrupted wave; based on an occurrence frequency and an influence proportion, an upstream wave characteristic comprises kinematic wave, dynamic wave, and hybrid wave; and a downstream wave characteristic comprises kinematic wave, dynamic wave, and interrupted wave.

9. The system for continuous routing forecasting and operation of the reservoir group under the influence of river fragmentation according to claim 8, wherein in the step S4, the enabling the dynamic coupled feedback computation between the operation process and the flood routing comprises:
S41: setting an operation objective for the reservoir in each constituent unit;
S42: sequentially adjusting reservoir operation modes in descending order of the information gains under different operation scenarios for the operation objective, and deriving an operation process for each operation mode;
S43: performing flood routing for upstream and downstream flood wave propagation processes respectively based on the reservoir inflow, outflow and elevation corresponding to the operation process; and
S44: determining whether the flood propagation process aligns with an expected operation objective;
if yes, continuing a computation with a downstream constituent unit; and
if not, adjusting the operation mode, and repeating the step S42 until the flood propagation process aligns with the expected operation objective.

10. The system for continuous routing forecasting and operation of the reservoir group under the influence of river fragmentation according to claim 9, wherein in the step S5, the completing the overall river system computation comprises:
S51: sequentially completing, through the steps S41 to S44, the reservoir operation process and upstream and downstream flood routing for each constituent unit; and
S52: sequentially invoking flood wave routing equations along a flow direction; sequentially computing elevations and flows at cross-sections of the constituent units and a river system from upstream to downstream, and obtaining an overall river system routing result for output.
